(19) United States
(12) Patent Application Publication
(10) Pub. No.: US 2024/0322779 A1
(43) Pub. Date: Sep. 26, 2024

(54) NOISE ELIMINATION CIRCUIT AND COMMUNICATION DEVICE INCLUDING THE SAME

(71) Applicants: Murata Manufacturing Co., Ltd., Nagaokakyo-shi (JP); NATIONAL UNIVERSITY CORPORATION TOYOHASHI UNIVERSITY OF TECHNOLOGY, Toyohashi-shi (JP)

(72) Inventors: Hiromasa SAEKI, Nagaokakyo-shi (JP); Masaya TAMURA, Toyohashi-shi (JP); Masaya TAKAGI, Toyohashi-shi (JP)

(21) Appl. No.: 18/733,924

(22) Filed: Jun. 5, 2024

Related U.S. Application Data
(63) Continuation of application No. PCT/JP2022/042885, filed on Nov. 18, 2022.

(30) Foreign Application Priority Data
Dec. 6, 2021 (JP) 2021-197974

(51) Int. Cl. H03H 7/01; H04B 1/525

(52) U.S. Cl. CPC H03H 7/0115; H03H 7/1775; H04B 1/525

(57) ABSTRACT

A noise elimination circuit includes a coupling line and a resonance unit, and is connected between a first transmission line and a second transmission line to eliminate noise between the first and second transmission lines. The coupling line is connected to the first and second transmission lines. The resonance unit includes a plurality of resonance circuits connected in parallel to the coupling line. A band pass filter includes the coupling line and the resonance unit. A real part and an imaginary part of an admittance between the transmission lines are canceled out by the noise elimination circuit.

### CROSS REFERENCE TO RELATED APPLICATIONS

This application claims the benefit of priority to Japanese Patent Application No. 2021-197974 filed on Dec. 6, 2021 and is a Continuation Application of PCT Application No. PCT/JP2022/042885 filed on Nov. 18, 2022. The entire contents of each application are hereby incorporated herein by reference.

### BACKGROUND OF THE INVENTION

### 1. Field of the Invention

The present disclosure relates to noise elimination circuits and communication devices including the same, and more specifically, to techniques of eliminating interference noise generated between two transmission lines.

### 2. Description of the Related Art

In recent years, communication traffic has been increasing rapidly as communication apparatuses increase, and there is widespread concern about network band shortage. As means for solving these problems, for example, a full-duplex communication method that enables communication at the same time and the same frequency is increasingly expected. Further, as another case, a technique such as a Massive-MIMO technique of mounting antennas with high density is also increasingly expected. In these cases, interference noise generated among a plurality of antennas during communication poses a problem.

Japanese Patent No. 6214673 discloses a wireless communication system in which a passive cancellation network including an attenuator and a phase shifter is connected between a transmitting line and a receiving line. In the wireless communication system in Japanese Patent No. 6214673, the passive cancellation network adjusts the amplitude and the phase of a transmitted signal and generates a cancellation signal, the cancellation signal is synthesized into the receiving line by a passive signal coupler, and thereby interference noise caused by the transmitted signal generated in a received signal is cancelled.

Further, Japanese Patent Laying-Open No. 2006-279309 discloses a wireless device in which a phase amplitude adjustment unit is connected between a transmitting antenna and a receiving antenna. The phase amplitude adjustment unit in Japanese Patent Laying-Open No. 2006-279309 receives a transmitted signal to be transmitted to the transmitting antenna and adjusts its phase and amplitude, adds a signal with a phase opposite to that of the transmitted signal to a received signal, and thereby attenuates a disturbing wave caused by the transmitted signal included in the received signal.

### SUMMARY OF THE INVENTION

From the viewpoint of practical convenience, it is desirable that noise generated between transmission lines can be eliminated at a wide band frequency. Further, in recent years, signals in a plurality of frequency bands may be transmitted and received using the same transmission line, and it is necessary to eliminate noise caused by each of the plurality of frequency bands.

To deal with such a problem, Japanese Patent No. 6214673 discloses, in FIG. 6, a passive cancellation network that can eliminate noise in a plurality of frequency bands. However, in the passive cancellation network, it is necessary to individually provide a set of an attenuator and a phase shifter for each frequency band as an elimination target. Thus, the passive cancellation network itself has a complicated configuration.

Example embodiments of the present invention reduce interference noise in a plurality of frequency bands, generated between two transmission lines, by a relatively simple configuration.

A noise elimination circuit according to a first aspect of an example embodiment of the present disclosure includes a coupling line and a resonance unit. The noise elimination circuit is connected between a first transmission line and a second transmission line to eliminate noise between the first and second transmission lines. The coupling line is connected to the first transmission line and the second transmission line. The resonance unit includes a plurality of resonance circuits connected in parallel to the coupling line. A band pass filter includes the coupling line and the resonance unit. A real part and an imaginary part of an admittance between the transmission lines are canceled out by the noise elimination circuit.

A communication device according to a second aspect of an example embodiment of the present disclosure includes a first antenna, a second antenna, and a noise elimination circuit. The first antenna is connected to a first transmission line. The second antenna is connected to a second transmission line. The noise elimination circuit is connected between the first transmission line and the second transmission line to eliminate noise between the first and second transmission lines. The noise elimination circuit includes a coupling line and a resonance unit. The coupling line is connected to the first transmission line and the second transmission line. The resonance unit includes a plurality of resonance circuits connected in parallel to the coupling line. A band pass filter includes the coupling line and the resonance unit. A real part and an imaginary part of an admittance between the transmission lines are canceled out by the noise elimination circuit.

In a noise elimination circuit according to an example embodiment of the present disclosure, the plurality of resonance circuits are connected in parallel with respect to the coupling line connected between the two transmission lines, and parameters of each resonator are adjusted such that the real part and the imaginary part of the admittance between the transmission lines are canceled out. In such a configuration, a signal in a desired frequency band can be eliminated by adjusting the position of an attenuation pole determined by each resonator. Therefore, interference noise in a plurality of frequency bands, generated between the two transmission lines, can be reduced by a relatively simple configuration.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is an overall schematic diagram of a communication device including a front end circuit including a noise elimination circuit according to a first example embodiment of the present invention.

FIG. 2 is a perspective view of the front end circuit in FIG. 1.

FIG. 3 is a plan view of the front end circuit in FIG. 1.

FIG. 4 is an equivalent circuit diagram of the noise elimination circuit in FIG. 1.

FIG. 5 is an equivalent circuit diagram of a noise elimination circuit in a first variation.

FIG. 6 is an equivalent circuit diagram of a noise elimination circuit in a second variation.

FIG. 7 is a first example of a schematic cross sectional view of the noise elimination circuit.

FIG. 8 is a second example of the schematic cross sectional view of the noise elimination circuit.

FIG. 9 is a third example of the schematic cross sectional view of the noise elimination circuit.

FIG. 10 is a first example of a case where a resonance unit and a coupling line are arranged separately.

FIG. 11 is a second example of the case where the resonance unit and the coupling line are arranged separately.

FIG. 12 shows antenna characteristics of front end circuits in the first example embodiment of the present invention and a first comparative example.

FIG. 13 shows an admittance characteristic between transmission lines in the front end circuit in the first example embodiment of the present invention.

FIG. 14 shows a configuration of a noise elimination circuit in a second example embodiment of the present invention.

FIG. 15 shows antenna characteristics in the noise elimination circuit in the second example embodiment of the present invention and a noise elimination circuit in a second comparative example.

FIG. 16 is an overall schematic diagram of a communication device according to a third example embodiment of the present invention.

FIG. 17 is an overall schematic diagram of a communication device according to a fourth example embodiment of the present invention.

### DETAILED DESCRIPTION OF THE EXAMPLE EMBODIMENTS

Hereinafter, example embodiments of the present disclosure will be described in detail with reference to the drawings. It is to be noted that identical or corresponding parts in the drawings will be designated by the same reference numerals, and the description thereof will not be repeated.

### First Example Embodiment

### Overall Configuration of Communication Device

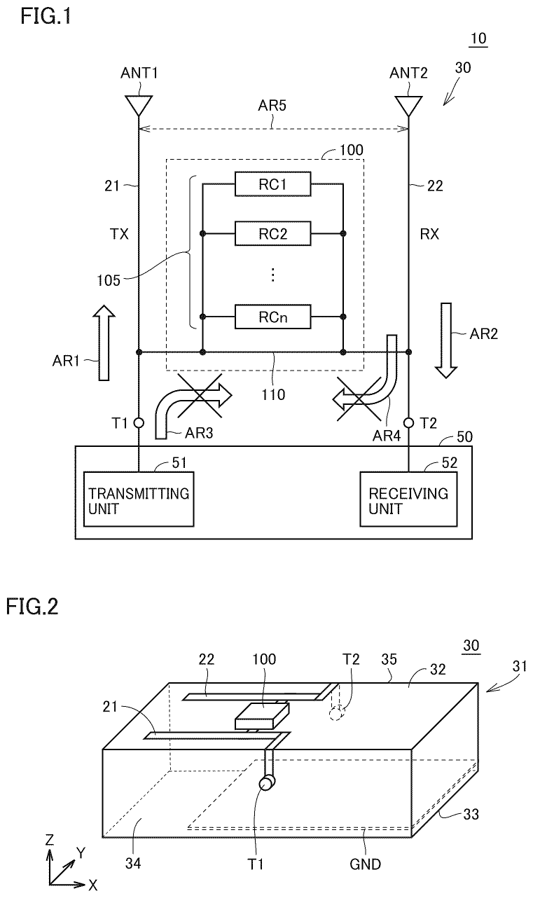

FIG. 1 is an overall schematic diagram of a communication device 10 including a noise elimination circuit 100 according to a first example embodiment. Referring to FIG. 1, communication device 10 includes a front end circuit 30 including noise elimination circuit 100, and a signal processing circuit 50.

In addition to noise elimination circuit 100, front end circuit 30 further includes a transmission line 21 (TX) connected to a transmitting antenna ANTI, and a transmission line 22 (RX) connected to a receiving antenna ANT2. Signal processing circuit 50 includes a transmitting unit 51 and a receiving unit 52.

Transmission line 21 is connected to transmitting unit 51 of signal processing circuit 50, at a terminal T1. A transmitted signal transmitted from transmitting unit 51 is transferred to antenna ANTI by transmission line 21, and is emitted as an electric wave from antenna ANT1 (an arrow AR1). Transmission line 22 is connected to receiving unit 52 of signal processing circuit 50, at a terminal T2. A received signal received by antenna ANT2 is transferred to receiving unit 52 by transmission line 22 (an arrow AR2). Receiving unit 52 processes the received signal, and further transfers the processed signal to a subsequent circuit not shown. It should be noted that transmission lines 21 and 22 may function as antennas ANT1 and ANT2, respectively.

Noise elimination circuit 100 includes a coupling line 110 connected to transmission line 21 and transmission line 22, and a resonance unit 105 connected in parallel to coupling line 110. Resonance unit 105 includes a plurality of resonance circuits RC1 to RCn (where n is a natural number more than or equal to 2), and the resonance circuits are connected in parallel to one another with respect to coupling line 110. By connecting each of resonance circuits RC1 to RCn included in noise elimination circuit 100 in parallel with coupling line 110, noise elimination circuit 100 alone functions as a band-pass filter.

When two transmission lines are arranged proximally as described above, electromagnetic field coupling may occur between the transmission lines. In that case, noise caused by the transmitted signal passing through transmission line 21 may be superimposed on receiving transmission line 22 due to the electromagnetic field coupling (an arrow AR3). Similarly, noise caused by the received signal passing through transmission line 22 may be superimposed on transmitting transmission line 21 due to the electromagnetic field coupling (an arrow AR4).

Furthermore, in a circuit as shown in FIG. 1, in addition to a direct coupling path such as coupling line 110, a path spatially coupled by the electromagnetic field coupling (an arrow AR5) exists between transmission line 21 and transmission lines 22. However, by designing parameters to cancel out a real part and an imaginary part of an admittance between transmission line 21 and transmission line 22, it is possible to conceive that coupling line 110 hypothetically includes the electromagnetic field coupling indicated by arrow AR5.

In noise elimination circuit 100 in the present first example embodiment, by designing parameters to cancel out the real part and the imaginary part of the admittance between transmission line 21 and transmission line 22 in consideration of arrow AR5, it is possible to reduce the noise caused by the transmitted signal from transmission line 21 to transmission line 22, and the noise caused by the received signal from transmission line 22 to transmission line 21. That is, noise elimination circuit 100 as a whole can function like a band-stop filter.

### Configuration of Front End Circuit

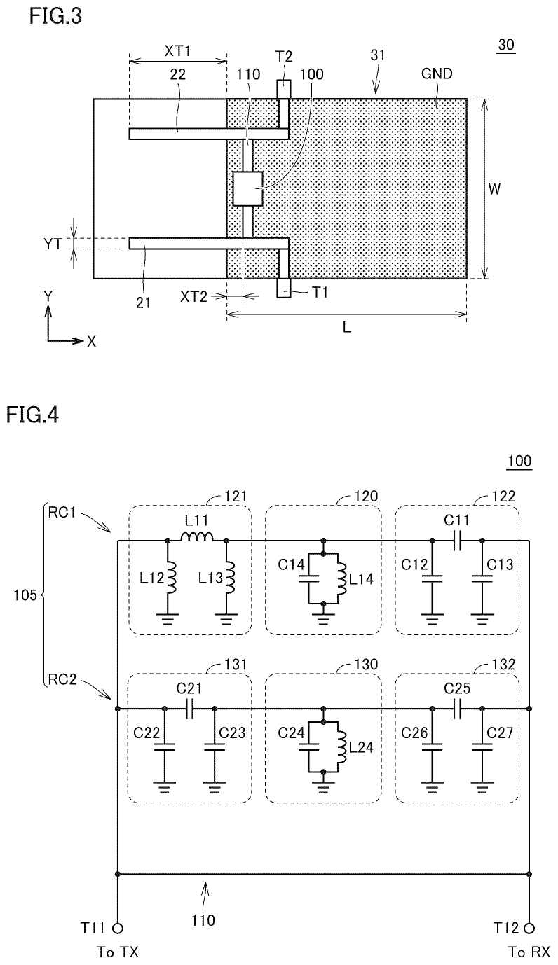

Next, a detailed configuration of front end circuit 30 will be described using FIGS. 2 and 3. FIG. 2 is a perspective view of front end circuit 30, and FIG. 3 is a plan view of front end circuit 30.

Referring to FIGS. 2 and 3, front end circuit 30 includes a dielectric substrate 31 and a ground electrode GND, in addition to transmission lines 21 and 22, noise elimination circuit 100, and terminals T1 and T2 described above. Dielectric substrate 31 has a shape of an approximately rectangular parallelepiped including rectangular or substantially rectangular main surfaces 32 and 33, for example. It should be noted that, in FIGS. 2 and 3, a normal direction of main surfaces 32 and 33 is defined as a Z-axis direction, a long-side direction of main surfaces 32 and 33 is defined as an X-axis direction, and a short-side direction of main surfaces 32 and 33 is defined as a Y-axis direction.

Transmission lines 21 and 22 and noise elimination circuit 100 are arranged on main surface 32 of dielectric substrate 31. One end of transmission line 21 is electrically connected to terminal T1 arranged on a side surface 34. One end of transmission line 22 is electrically connected to terminal T2 arranged on a side surface 35.

Ground electrode GND is arranged on main surface 33, or at an inner layer close to main surface 33, in dielectric substrate 31. As shown in FIG. 3, when viewed in a plan view from the normal direction of main surface 32, ground electrode GND extends over an entire length W of a short side along the Y-axis direction, and ground electrode GND is arranged in the X-axis direction to overlap with noise elimination circuit 100 and portions of transmission lines 21 and 22. By arranging the elements as described above, transmission lines 21 and 22 function as monopole antennas.

It should be noted that, in an example, ground electrode GND has a length L in the X-axis direction of about 52 mm, and length W in the Y-axis direction of about 37.6 mm, for example. Further, transmission lines 21 and 22 have a line width YT of about 1.7 mm and a protruding amount XT1 from ground electrode GND of about 23.3 mm, for example. A distance XT2 between coupling line 110 and an end portion of ground electrode GND is about 4.5 mm, for example. Further, dielectric substrate 31 has a dielectric constant ε of about 3.4, for example.

### Configuration of Noise Elimination Circuit

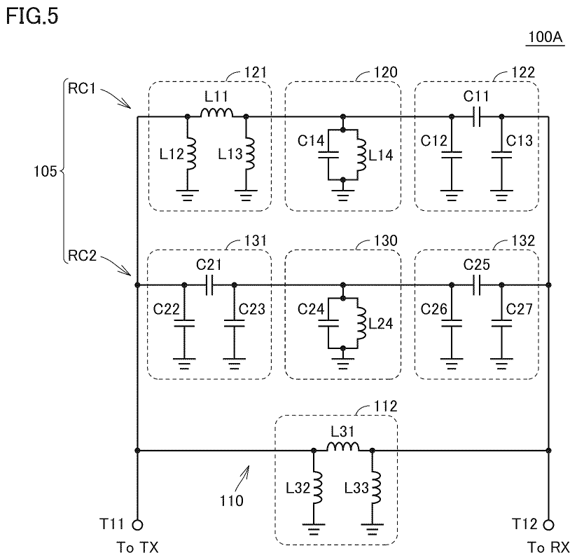

Next, a detailed configuration of noise elimination circuit 100 will be described. FIG. 4 is an equivalent circuit diagram of the noise elimination circuit in FIG. 1. It should be noted that, in the example of noise elimination circuit 100 in FIG. 4, resonance unit 105 includes two resonance circuits RC1 and RC2.

Referring to FIG. 4, in noise elimination circuit 100, coupling line 110 is a short circuit line that directly connects transmission line 21 (TX) and transmission line 22 (RX). Resonance circuit RC1 includes a resonator 120 and immittance inverters 121 and 122. Immittance inverter 121 is connected to transmission line 21, and immittance inverter 122 is connected to transmission line 22. Resonator 120 is connected between immittance inverter 121 and immittance inverter 122.

Immittance inverter is a J inverter including inductors L11, L12, and L13 connected in a m shape. Further, immittance inverter 122 is a J inverter including capacitors C11, C12, and C13 connected in a m shape. Resonator 120 is an LC parallel resonator including an inductor L14 and a capacitor C14 connected in parallel between a ground potential and a connection node between immittance inverter 121 and immittance inverter 122.

Resonance circuit RC2 a resonator 130 and immittance inverters 131 and 132. Immittance inverter 131 is connected to transmission line 21, and immittance inverter 132 is connected to transmission line 22. Resonator 130 is connected between immittance inverter 131 and immittance inverter 132.

Immittance inverter 131 is a J inverter including capacitors C21, C22, and C23 connected in a x shape. Further, Immittance inverter 132 is a J inverter including capacitors C25, C26, and C27 connected in a x shape. Resonator 130 is an LC parallel resonator including an inductor L24 and a capacitor C24 connected in parallel between the ground potential and a connection node between immittance inverter 131 and immittance inverter 132.

In this manner, resonance circuits RC1 and RC2 each function as a band-pass filter, using an LC parallel resonator and J inverters. In addition, by connecting resonance circuits RC1 and RC2 in parallel with respect to coupling line 110 adjusted in consideration of the electromagnetic field coupling between the transmission lines indicated by arrow AR5 in FIG. 1, noise elimination circuit 100 as a whole functions as a band-stop filter.

The plurality of resonance circuits include at least one resonance circuit in an odd mode with an asymmetrical inverter configuration, such as resonance circuit RC1, and at least one resonance circuit in an even mode with a symmetrical inverter configuration, such as resonance circuit RC2. When the total number of resonance circuits is an even number, it is more preferable to provide the same number of resonance circuits in the odd mode and resonance circuits in the even mode. Further, when an LC series resonator is used as a resonator included in each resonance circuit, the same function as that described above can be achieved by using a K inverter having inductors or capacitors arranged in a T shape, as an immittance inverter.

It should be noted that, as in a noise elimination circuit 100A in a first variation shown in FIG. 5, coupling line 110 may be provided with an additional circuit 112 including inductors L31, L32, and L33 arranged in a x shape.

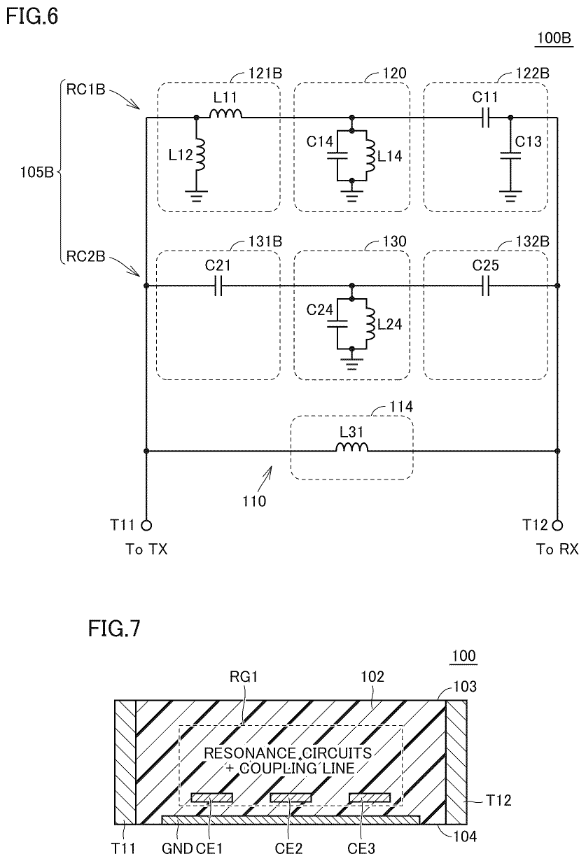

Further, as in a noise elimination circuit 100B in a second variation shown in FIG. 6, shunt elements (for example, inverters or capacitors) connected to the ground potential may be partially reduced in each inverter, by parity of the resonance modes and/or synthesis with an inductor and a capacitor included in a resonator. More specifically, in noise elimination circuit 100B in FIG. 6, an immittance inverter 121B in a resonance circuit RC1B has a configuration in which inductor L13 in immittance inverter 121 in FIG. 4 is removed. Further, an immittance inverter 122B has a configuration in which capacitor C12 in immittance inverter 122 in FIG. 4 is removed.

Similarly, in a resonance circuit RC2B, an immittance inverter 131B has a configuration in which capacitors C22 and C23 in immittance inverter 131 in FIG. 4 are removed, and an immittance inverter 132B has a configuration in which capacitors C26 and C27 in immittance inverter 132 in FIG. 4 are removed.

Furthermore, in noise elimination circuit 100B, coupling line 110 is provided with inductor L31 as an additional circuit 114.

The noise elimination circuits shown in FIGS. 4 to 6 can each be including a combination of inductors and capacitors, as described above. In the noise elimination circuit in the first example embodiment, the immittance inverter and the resonator are defined using a circuit pattern and a via arranged within a dielectric layer. The dielectric layer has, for example, a multi-layer structure in which electrodes like copper foil and dielectrics are stacked in layers, and an inductor and a capacitor are structured to be three-dimensional in a stacking direction of the dielectrics using a via. It should be noted that the dielectric layer is not necessarily limited to have a multi-layer structure, and may have a single-layer structure. Further, the dielectric layer may include a plurality of materials.

Further, the noise elimination circuit may have a planar structure including a conductor drawn on a dielectric plane, without using a three-dimensional structure as described above. The noise elimination circuit may include discrete elements as elements of the immittance inverter and the resonator. When the resonator includes discrete elements, a surface acoustic wave (SAW) resonator or a film bulk acoustic resonator (FBAR) may be used.

By forming the noise elimination circuit to have a three-dimensional structure as in the first example embodiment, the projection area of the noise elimination circuit can be decreased, and the entire front end circuit can be reduced in size.

FIG. 7 is a schematic cross sectional view of noise elimination circuit 100. Noise elimination circuit 100 includes a dielectric layer 102 as described above. In a region RG1 within dielectric layer 102, resonance unit 105 and coupling line 110 include a circuit pattern and a via. Ground electrode GND is arranged on a lower surface 104 side of dielectric layer 102, and terminals T11 and T12 for connection to transmission lines 21 and 22 are arranged on side surfaces of dielectric layer 102.

In noise elimination circuit 100, it is necessary to precisely control the values of an inductance and a capacitance included in a resonator and an immittance inverter of each resonance circuit, and it is important to design the capacitance which is particularly susceptible to temperature dependency. Accordingly, it is desirable that a dielectric constant temperature coefficient of dielectric layer 102 is as small as possible. Specifically, the dielectric constant temperature coefficient is preferably within a range of about −200 to about +200 ppm/K, and more desirably, is preferably within a range of about −100 to about +100 ppm/K, at close to room temperature (for example, at about 25° C.), for example.

As dielectric layer 102, for example, a low temperature co-fired ceramic (LTCC) can be used. It should be noted that, in order to satisfy a desired Q value, it is preferable to use silver (Ag) or gold (Au) as an inner conductor. Also, it is preferable to form dielectric layer 102 using an LTCC including more than or equal to about 50% by weight and less than or equal to about 80% by weight of a glass component, for example.

Further, as another dielectric material for dielectric layer 102, a material mainly including a fluororesin, a liquid crystal polymer, poly phenylene ether (PPE), LiNbO₃, or LiTaO₃ can be used. Furthermore, as another configuration of dielectric layer 102, a dielectric thin film mainly including SiO₂ or SiN formed on a silicon substrate using a CVD method, a sputtering method, or the like may be used.

In noise elimination circuit 100, it is desirable to use a ground electrode GND1 as one electrode of a capacitor included in resonator 120, 130. The characteristics of noise elimination circuit 100 tend to significantly depend on the characteristics of resonators 120 and 130 within resonance unit 105. When both electrodes of the capacitor included in resonator 120, 130 are arranged to be separated from ground electrode GND1, parasitic capacitance may occur in these electrodes and a via, and thus there is a possibility that the characteristics of the resonators may vary due to manufacturing variations and the like, and desired characteristics may not be obtained. By providing the capacitor included in resonator 120, 130 as described above using ground electrode GND1 and an electrode facing ground electrode GND1 (for example, electrodes CE1 to CE2 and the like) to decrease or minimize a wiring distance and reduce parasitic capacitance, a more stable circuit can be achieved.

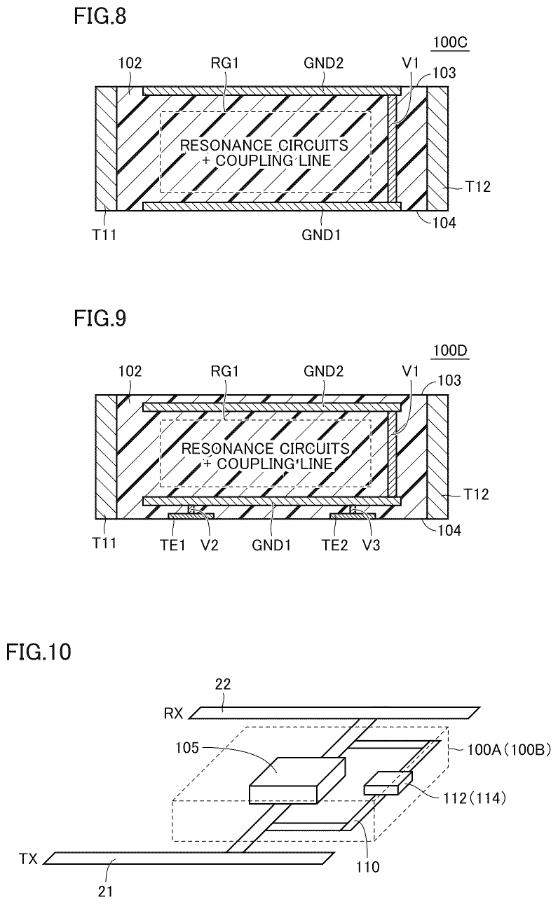

FIG. 8 is a schematic cross sectional view of a noise elimination circuit 100C. In noise elimination circuit 100C, in addition to ground electrode GND1 arranged on lower surface 104 of dielectric layer 102, a ground electrode GND2 is also arranged on an upper surface 103. Ground electrode GND2 is electrically connected with ground electrode GND1 through a via V1 or an electrode (not shown) arranged on the side surface of dielectric layer 102. In addition, resonance unit 105 and coupling line 110 are arranged between ground electrode GND1 and ground electrode GND2 in dielectric layer 102 (region RG1). By arranging resonance unit 105 and coupling line 110 (especially, resonance unit 105) between two ground electrodes GND1 and GND2 in this manner, ground electrodes GND1 and GND2 function as shields, and thereby can reduce influence of parasitic capacitance by an external apparatus or the like on noise elimination circuit 100C.

It should be noted that ground electrodes GND1 and GND2 do not necessarily have to be exposed to lower surface 104 and upper surface 103 of dielectric layer 102. For example, at least one of ground electrodes GND1 and GND2 may be arranged on an inner layer of dielectric layer 102, as in a noise elimination circuit 100D in FIG. 9. When ground electrode GND1 is arranged on the inner layer, connection terminals TE1 and TE2 for connection with dielectric substrate 31 on which dielectric layer 102 is mounted are provided on lower surface 104, and connection terminals TE1 and TE2 are connected to ground electrode GND1 by vias V2 and V3, respectively. Also in this case, by arranging resonance unit 105 and coupling line 110 between ground electrode GND1 and ground electrode GND2, influence of parasitic capacitance by an external apparatus or the like can be reduced.

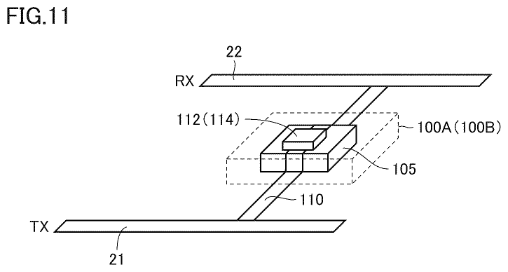

Although the above description has been given with respect to a case where the noise elimination circuits in FIGS. 7 to 9 have a package structure in which resonance unit 105 and coupling line 110 are arranged within common dielectric layer 102, coupling line 110 does not necessarily have to be formed integrally with resonance unit 105. For example, coupling line 110 may be arranged on dielectric substrate 31 to be separated from resonance unit 105, as shown in FIG. 10.

When coupling line 110 is provided with additional circuit 112, 114 as in noise elimination circuits 100A and 100B illustrated in FIGS. 5 and 6, coupling line 110 can be defined as an element separate from resonance unit 105, by adopting a configuration that coupling line 110 is separated as shown in FIG. 10. Although coupling line 110 can be designed to include the electromagnetic field coupling between transmission lines 21 and 22 as described above, the coupling between transmission lines 21 and 22 may vary depending on the type and the shape of the transmission lines (antennas). Accordingly, by arranging coupling line 110 to be separated from resonance unit 105, it is possible to appropriately adjust the value(s) of an inductance and/or a capacitance of a reactance element (an inductor, a capacitor) in the additional circuit according to the type and the shape of the transmission lines (antennas).

It should be noted that the additional circuit may be an individual element as shown in FIG. 10, or may be a wire or a stub provided on dielectric substrate 31. Further, coupling line 110 does not necessarily have to be provided on dielectric substrate 31, and may run along the side surfaces and the upper surface of dielectric layer 102 included in resonance unit 105 as shown in FIG. 11, for example. In this case, additional circuit 112, 114 is arranged on the upper surface of dielectric layer 102.

### Antenna Characteristics

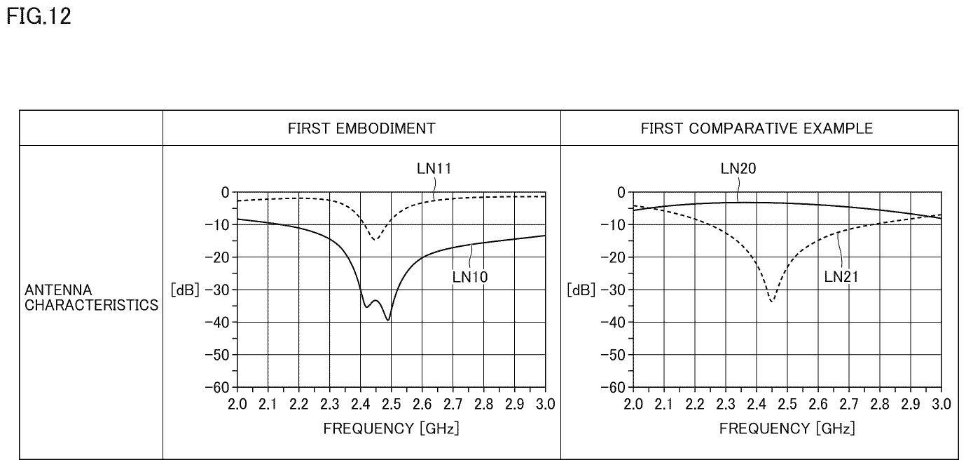

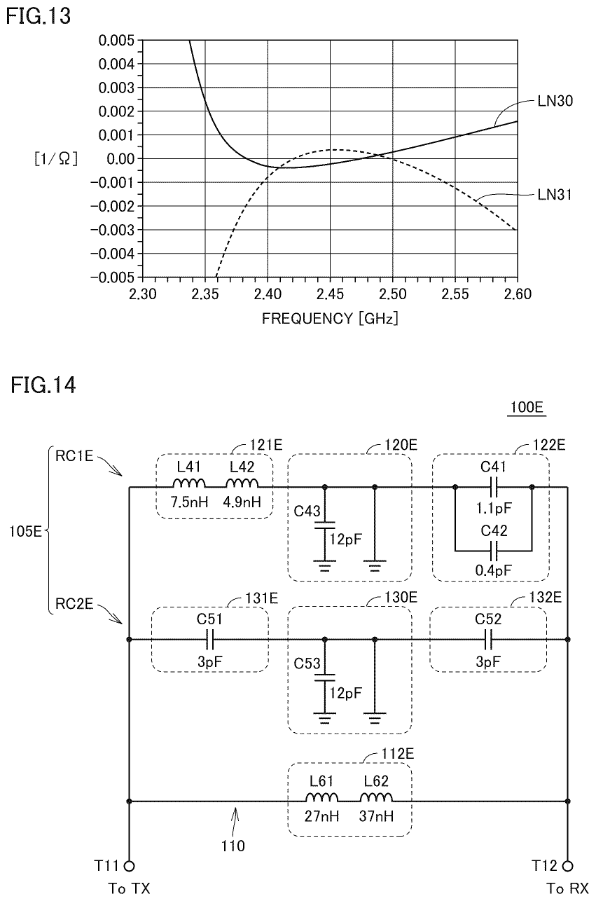

Next, antenna characteristics in the front end circuit of the first example embodiment will be described using FIGS. 12 and 13.

FIG. 12 shows a simulation result of antenna characteristics in front end circuit 30 in the first example embodiment and a front end circuit in a first comparative example that does not include a noise elimination circuit. In FIG. 12, solid lines LN10 and LN20 each indicate an insertion loss from terminal T1 to terminal T2 (that is, isolation between terminal T1 and terminal T2), and broken lines LN11 and LN21 each indicate a return loss in terminal T1 on a transmitting side. It should be noted that, in the simulation, the 2.4 GHz band (for example, about 2.4 GHz to about 2.5 GHz) is set as a frequency band as a noise elimination target.

Referring to FIG. 12, in the first comparative example (the right graph), the return loss (broken line LN21) has an extreme value at near 2.45 GHZ, whereas the isolation (solid line LN20) is about −5 dB in the entire frequency range, and coupling occurs between transmission line 21 on the transmitting side and transmission line 22 on a receiving side.

In contrast, in the case of the first example embodiment (the left graph), the isolation has extreme values at near 2.42 GHz and 2.5 GHz by two resonance circuits, and an attenuation amount of more than or equal to about −30 dB is achieved in a noise elimination target range of about 2.4 GHz to about 2.5 GHZ, for example. In this simulation, resonator 120 in resonance circuit RC1 has a resonance frequency of about 2.18 GHZ, and resonator 130 in resonance circuit RC2 has a resonance frequency of about 2.75 GHz, for example. It should be noted that, for characteristic values of the inductors and the capacitors of the immittance inverters in each resonance circuit, optimization computation is performed using Keysight Advanced Design System.

FIG. 13 is a view showing an admittance characteristic between the transmission lines in front end circuit 30 in the first example embodiment. In FIG. 13, a solid line LN30 indicates the real part of the admittance, and a broken line LN31 indicates the imaginary part of the admittance. As shown in FIG. 13, in the vicinity of the noise elimination target range of about 2.4 GHz to about 2.5 GHZ, the real part and the imaginary part of the admittance are canceled out, and values within a range of about −0.001 to about +0.001 [1/Ω], for example, are obtained. That is, in the noise elimination target range described above, coupling between the transmission lines is reduced or prevented.

As described above, in front end circuit 30 in the first example embodiment, by arranging, between two transmission lines 21 and 22, noise elimination circuit 100 having coupling line 110 connected to transmission lines 21 and 22 and resonance circuits RC1 and RC2 connected in parallel to coupling line 110, and by determining the characteristic values of the inductors and the capacitors included in noise elimination circuit 100 to cancel out the real part and the imaginary part of the admittance between the transmission lines in a desired frequency band, an attenuation amount in a plurality of frequency bands can be secured. In addition, by adjusting an attenuation pole in each resonance circuit, interference noise in a different frequency band, or interference noise in a wider frequency band, generated between the transmission lines can be reduced.

It should be noted that, although the example of the first example embodiment has described an example of the configuration that the noise elimination circuit includes two resonance circuits, it is possible to expand the range of a frequency band in which noise can be eliminated, or to eliminate noise generated in a distant frequency band, by increasing the number of resonance circuits included in the noise elimination circuit, and adjusting the attenuation pole in each resonance circuit.

It should be noted that “antenna ANT1” and “antenna ANT2” in the first example embodiment correspond to a “first antenna” and a “second antenna” in the present disclosure, respectively. “Transmission line 21” and “transmission line 22” in the first example embodiment correspond to a “first transmission line” and a “second transmission line” in the present disclosure, respectively. “Ground electrode GND1” and “ground electrode GND2” in the first example embodiment correspond to a “first ground electrode” and a “second ground electrode” in the present disclosure, respectively. Each of “additional circuits 112 and 114” in the present first example embodiment corresponds to a “first circuit” in the present disclosure.

### Second Example Embodiment

A second example embodiment will describe a configuration in which the noise elimination circuit in the present disclosure is applied to a communication device for the 830 MHZ band, for example. The communication device in the second example embodiment has basically the same configuration as that in FIGS. 1 to 3, and a noise elimination circuit is provided between two monopole antennas. It should be noted that, in the example of the second example embodiment, ground electrode GND in FIG. 3 has length L in the X-axis direction of about 24 mm, and length W in the Y-axis direction of about 68.3 mm, for example. Further, transmission lines 21 and 22 have line width YT of about 1.7 mm and protruding amount XT1 from ground electrode GND of about 74 mm, and distance XT2 between coupling line 110 and an end portion of ground electrode GND is about 9 mm, for example.

FIG. 14 is an equivalent circuit diagram of a noise elimination circuit 100E in the second example embodiment. Referring to FIG. 14, a resonance unit 105E in noise elimination circuit 100E includes resonance circuits RC1E and RC2E connected in parallel to coupling line 110. It should be noted that, in noise elimination circuit 100E, discrete elements are used as inductors and capacitors included in the circuit.

Resonance circuit RC1E includes an immittance inverter 121E connected to transmission line 21, an immittance inverter 122E connected to transmission line 22, and a resonator 120E connected between immittance inverter 121E and immittance inverter 122E. Immittance inverter 121E includes inductors L41 and L42 connected in series. Immittance inverter 122E includes capacitors C41 and C42 connected in parallel. Inductor L41 has an inductance value of about 7.5 nH, and inductor L42 has an inductance value of about 4.9 nH, for example. Capacitor C41 has a capacitance value of about 1.1 pF, and capacitor C42 has a capacitance value of about 0.4 pF, for example.

Resonator 120E includes a capacitor C43 connected between a ground potential and a connection node between immittance inverter 121E and immittance inverter 122E, and a short circuit path that short-circuits the ground potential and the connection node. An LC resonance circuit includes an inductance of the short circuit path and capacitor C43. Capacitor C43 has a capacitance value of about 12 pF, for example.

Resonance circuit RC2E includes an immittance inverter 131E connected to transmission line 21, an immittance inverter 132E connected to transmission line 22, and a resonator 130E connected between immittance inverter 131E and immittance inverter 132E. Immittance inverter 131E includes a capacitor C51, and immittance inverter 132E includes a capacitor C52. Further, as with resonator 120E, resonator 130E includes a capacitor C53 connected between the ground potential and a connection node between immittance inverter 131E and immittance inverter 132E, and a short circuit path that short-circuits the ground potential and the connection node. Each of capacitors C51 and C52 has a capacitance value of about 3 pF, and capacitor C53 has a capacitance value of about 12 pF, for example.

Further, coupling line 110 is provided with an additional circuit 112E including inductors L61 and L62 connected in series. Inductor L61 has an inductance value of about 27 nH, and inductor L62 has an inductance value of about 37 nH, for example.

It should be noted that the short circuit path in resonator 120E, 130E functions as an inductor having a very small inductance value. The short circuit path defines an LC parallel resonator with the capacitor connected in parallel. Resonator 120E has a resonance frequency of about 802.89 MHz, and resonator 130E has a resonance frequency of about 873.54 MHz, for example.

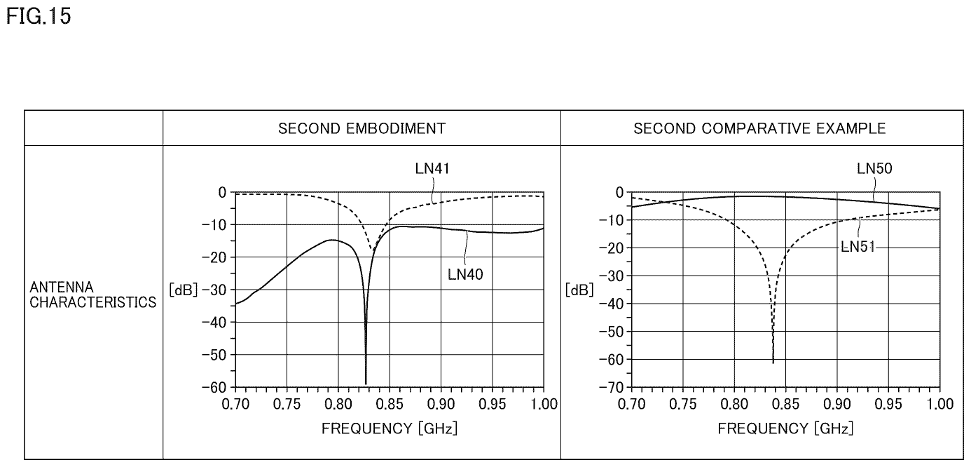

FIG. 15 shows a simulation result of antenna characteristics in a front end circuit in the second example embodiment and a front end circuit in a second comparative example that does not include a noise elimination circuit. Also in FIG. 15, solid lines LN40 and LN50 each indicate isolation between terminal T1 and terminal T2, and broken lines LN41 and LN51 each indicate a return loss in terminal T1 on a transmitting side.

Referring to FIG. 15, in the second comparative example (the right graph), the return loss (broken line LN51) has an extreme value at near about 840 MHz, whereas the isolation (solid line LN50) is less than or equal to about −5 dB in the entire frequency range, for example, and coupling occurs between transmission line 21 on the transmitting side and transmission line 22 on a receiving side.

In contrast, in the case of the second example embodiment (the left graph), the isolation has an extreme value at near about 825 MHz, and an attenuation amount of more than or equal to about −20 dB is achieved in a noise elimination target range of about 815 MHz to about 830 MHz, for example. In this manner, in the noise elimination circuit in the second example embodiment, coupling between the transmission lines is prevented for a signal at about 830 MHz to be transmitted, and thus interference noise between the transmission lines can be reduced.

### Third Example Embodiment

The first and second example embodiments have described the case of eliminating interference noise between the transmission line for the transmitted signal and the transmission line for the received signal. A third example embodiment will describe a configuration in which the noise elimination circuit in the present disclosure is applied to a communication device including a plurality of transmitting antennas arranged proximally.

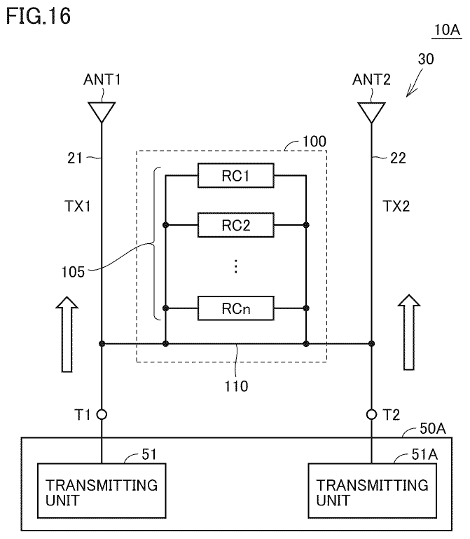

FIG. 16 is an overall schematic diagram of a communication device 10A according to the third example embodiment. In communication device 10A, both transmission line 21 and transmission line 22 are used as paths for transferring a transmitted signal (TX1, TX2). Transmission line 21 is connected to transmitting unit 51 included in a signal processing circuit 50A, at terminal T1. Further, transmission line 22 is connected to a transmitting unit 51A included in signal processing circuit 50A, at terminal T2. Also in communication device 10A, noise elimination circuit 100 is connected between transmission line 21 and transmission line 22.

Thus, also in the communication device including the plurality of transmitting antennas included therein, by providing the noise elimination circuit between the transmitting transmission lines arranged proximally, interference noise generated between the transmission lines due to electromagnetic field coupling can be reduced.

### Fourth Example Embodiment

A fourth example embodiment will describe a configuration in which the noise elimination circuit in the present disclosure is applied to a communication device including a plurality of receiving antennas arranged proximally.

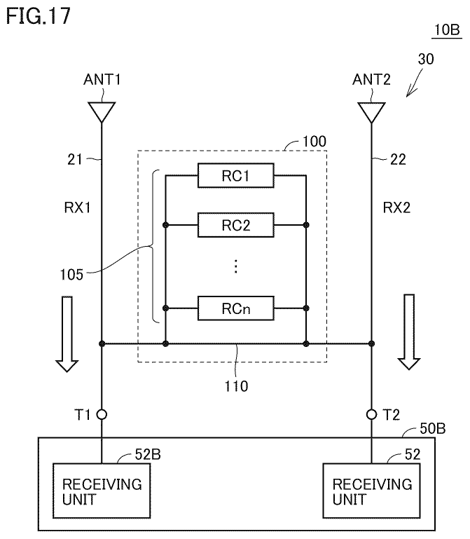

FIG. 17 is an overall schematic diagram of a communication device 10B according to the fourth example embodiment. In communication device 10B, both transmission line 21 and transmission line 22 are used as paths to transfer a received signal (RX1, RX2). Transmission line 21 is connected to a receiving unit 52B included in a signal processing circuit 50B, at terminal T1. Further, transmission line 22 is connected to receiving unit 52 included in signal processing circuit 50B, at terminal T2. Also in communication device 10B, noise elimination circuit 100 is connected between transmission line 21 and transmission line 22.

Thus, also in the communication device including the plurality of receiving antennas provided therein, by providing the noise elimination circuit between the receiving transmission lines arranged proximally, interference noise generated between the transmission lines due to electromagnetic field coupling can be reduced.

It should be noted that, although the above description has been given of the case where the two transmission lines function as antennas, and the case where the two transmission lines are lines connected to antennas, the two transmission lines do not necessarily have to be lines related to antennas. That is, a noise elimination circuit according to an example embodiment of the present disclosure is also applicable to a transmission line other than an antenna that transfers a radio frequency signal.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A noise elimination circuit connected between a first transmission line and a second transmission line to eliminate noise between the first and second transmission lines, the noise elimination circuit comprising:
a coupling line connected to the first transmission line and the second transmission line; and
a resonance unit including a plurality of resonance circuits connected in parallel to the coupling line; wherein
a band pass filter includes the coupling line and the resonance unit; and
a real part and an imaginary part of an admittance between the transmission lines are canceled out by the noise elimination circuit.

2. The noise elimination circuit according to claim 1, further comprising a dielectric layer, wherein
the resonance unit includes a circuit pattern and a via within the dielectric layer.

3. The noise elimination circuit according to claim 2, wherein
each of the plurality of resonance circuits includes a resonator including a capacitor and an inductor connected in parallel; and
a resonance frequency of the resonator is set to generate an attenuation pole in a frequency band of the noise to be eliminated between the first and second transmission lines.

4. The noise elimination circuit according to claim 3, further comprising a first ground electrode with a flat plate shape and provided in the dielectric layer, wherein
the first ground electrode is one electrode of the capacitor included in the resonator.

5. The noise elimination circuit according to claim 4, further comprising a second ground electrode provided in the dielectric layer to face the first ground electrode, and electrically connected with the first ground electrode; wherein
the coupling line and the resonance unit are between the first ground electrode and the second ground electrode in the dielectric layer.

6. The noise elimination circuit according to claim 5, wherein at least one of the first ground electrode and the second ground electrode is exposed to an outer surface of the dielectric layer.

7. The noise elimination circuit according to claim 2, wherein the coupling line is within the dielectric layer.

8. The noise elimination circuit according to claim 2, wherein
the first transmission line, the second transmission line, and the noise elimination circuit are on a dielectric substrate; and
on the dielectric substrate, the coupling line is separated from the resonance unit.

9. The noise elimination circuit according to claim 2, wherein a dielectric constant temperature coefficient of the dielectric layer is within a range of more than about −100 ppm/K and less than about +100 ppm/K.

10. The noise elimination circuit according to claim 2, wherein the dielectric layer is made of a low temperature co-fired ceramic including more than or equal to about 50% by weight and less than or equal to about 80% by weight of a glass component.

11. The noise elimination circuit according to claim 2, wherein the dielectric layer includes a material mainly including SiO₂, SiN, a fluororesin, a liquid crystal polymer, poly phenylene ether (PPE), LiNbO₃, or LiTaO₃.

12. The noise elimination circuit according to claim 2, further comprising a first circuit provided to the coupling line and including a reactance element.

13. The noise elimination circuit according to claim 12, wherein the first circuit is on the dielectric layer.

14. The noise elimination circuit according to claim 1, wherein the resonance unit includes a capacitor and an inductor including discrete elements.

15. A communication device comprising:
a first antenna connected to a first transmission line;
a second antenna connected to a second transmission line; and
a noise elimination circuit connected between the first transmission line and the second transmission line to eliminate noise between the transmission lines; wherein
the noise elimination circuit includes:
a coupling line connected to the first transmission line and the second transmission line; and
a resonance unit including a plurality of resonance circuits connected in parallel to the coupling line;
a band pass filter includes the coupling line and the resonance unit; and
a real part and an imaginary part of an admittance between the transmission lines are canceled out by the noise elimination circuit.

16. The communication device according to claim 15, wherein the first antenna is a transmitting antenna, and the second antenna is a receiving antenna.

17. The communication device according to claim 15, wherein the first antenna and the second antenna are transmitting antennas.

18. The communication device according to claim 15, wherein the first antenna and the second antenna are receiving antennas.

19. The communication device according to claim 15, further comprising a front end circuit that includes the noise elimination circuit.

20. The communication device according to claim 19, wherein the front end circuit further includes a signal processing circuit.
